(19) United States
(12) Patent Application Publication
(10) Pub. No.: US 2025/0264809 A1
(43) Pub. Date: Aug. 21, 2025

(54) OPTICAL SYSTEM AND LITHOGRAPHY APPARATUS HAVING AN OPTICAL SYSTEM

(71) Applicant: Carl Zeiss SMT GmbH, Oberkochen (DE)

(72) Inventor: Steffen VAAS, Ellwangen (DE)

(21) Appl. No.: 19/199,730

(22) Filed: May 6, 2025

Related U.S. Application Data
(63) Continuation of application No. PCT/EP2023/080825, filed on Nov. 6, 2023.

(30) Foreign Application Priority Data
Nov. 7, 2022 (DE) 10 2022 211 696.8

(51) Int. Cl. G03F 7/00; G02B 7/182; G02B 17/06

(52) U.S. Cl. CPC G03F 7/70508; G02B 7/182; G02B 17/0663; G03F 7/70525; G03F 7/70841; G03F 7/7085; G03F 7/70991

(57) ABSTRACT

An optical system for a lithography apparatus comprises a plurality of optical elements, having: a number N1 of arrangements, where N1≥1, wherein each of the N1 arrangements comprises at least one actuator/sensor device assigned to one of the optical elements; a plurality N2 of local drive units for driving the number N1 of arrangements where N2≥2; and a number N3 of central drive units for driving the N2 local drive units, where N3≥1. Each of the N1 arrangements is connected to at least one of the N2 local drive units via a primary connection and a secondary connection, which is redundant with respect to the primary connection. One of the connections is usable as an active connection for data transmission, and the other of the connections is inactive.

### CROSS-REFERENCE TO RELATED APPLICATIONS

The present application is a continuation of, and claims benefit under 35 USC 120 to, international application No. PCT/EP2023/080825, filed Nov. 6, 2023, which claims benefit under 35 USC 119 of German Application No. 10 2022 211 696.8, filed Nov. 7, 2022. The entire disclosure of each of these applications is incorporated by reference herein.

### FIELD

The present disclosure relates to an optical system and to a lithography apparatus having such an optical system.

### BACKGROUND

Microlithography is used for producing microstructured components, such as for example integrated circuits. The microlithography process is carried out using a lithography apparatus, which comprises an illumination system and a projection system. The image of a mask (reticle) illuminated via the illumination system is projected via the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, EUV lithography apparatuses which use light with a wavelength in the range of 0.1 nanometer (nm) to 30 nm, for example 13.5 nm, are currently being developed. Since most materials absorb light of this wavelength, such EUV lithography apparatuses typically use reflective optical units, such as mirrors, instead of refractive optical units, such as lens elements, as used previously.

A multiplicity of actuator/sensor devices, such as sensors and actuators, are often installed in lithography apparatuses. In general, an actuator/sensor device is suitable for displacing an optical element, for example a mirror, assigned to the actuator/sensor device and/or for detecting a parameter of the assigned optical element, for instance a position of the assigned optical element or a temperature of the assigned optical element.

For driving and evaluation purposes, such an actuator/sensor device should be electrically connected to an electronic component, such as to an integrated circuit (IC).

The document DE 10 2015 224 742 A1 proposes a lithography apparatus which comprises a radiation source for generating radiation, a plurality of optical components for guiding the radiation in the apparatus, a number N1 of arrangements, where N1≥1, wherein each of the N1 arrangements comprises at least one actuator/sensor device which is assigned to one of the optical components, a plurality N2 of local drive units for driving the number N1 of arrangements, where N2≥2, and a number N3 of central drive units for driving the N2 local drive units, where N3≥1. The distributed driving of the actuator/sensor devices via the local drive units and the central drive units makes it possible to distribute the heat that arises as a result of the driving. As a result, hot spots, for example in the vacuum housing of the lithography apparatus, are avoided and the heat distribution is harmonized and optimized.

The respective one pertaining to the N1 arrangement is connected to one of the local drive units via a connection for data exchange purposes. However, it is possible for such a connection to fail or to be affected by a fault after some time.

The exchange of electronic components, such as for example such connections affected by a fault between an actuator/sensor device and a drive unit, in an optical system of a lithography apparatus, such as within the vacuum region, can involve a relatively large time expenditure until the system is in operational service again.

A modular setup, as described for example in the document DE 10 2015 224 724 A1 cited above, does make it possible to reduce the maintenance time and the maintenance costs, with an increasing number of connections between the modules, that is to say for example the actuator/sensor devices and the drive units, but the frequency of faults can increase as well, particularly when there are hundreds of electrical connections between the modules.

### SUMMARY

The present disclosure seeks to provide an improved optical system.

In accordance with a first aspect, an optical system for a lithography apparatus comprising a plurality of optical elements is proposed, which has:
a number N1 of arrangements, where N1≥1, wherein each of the N1 arrangements comprises at least one actuator/sensor device assigned to one of the optical elements,
a plurality N2 of local drive units for driving the number N1 of arrangements, where N2≥2, and
a number N3 of central drive units for driving the N2 local drive units, where N3≥1,
wherein each of the N1 arrangements is connected to at least one of the N2 local drive units via a primary connection and a secondary connection, which is redundant with respect to the primary connection, wherein one of the connections is usable as an active connection for data transmission and the other of the connections is inactive,
wherein each of the N2 local drive units has a plurality N4, where N4≥2, of interface devices for respectively establishing the primary connection or the secondary connection to one of the N1 arrangements, a fault detection unit for detecting a fault of one of the active connections of a specific one of the N1 arrangements, and a providing unit for providing switchover information for switching over the active connection having a detected fault to the inactive connection of the specific arrangement.

Hereinafter, that local drive unit which provides the active connection having the detected fault is also referred to as first local drive unit, whereas that local drive unit which provides the connection which is redundant with respect thereto is referred to as second local drive unit.

By virtue of the use of the redundant connections between each of the N1 arrangements and the local drive units, the fault detection unit and the providing unit for switching over between the redundant connections, the present optical system can be significantly more failsafe than conventional optical systems. If a specific active connection used for data transmission between one of the arrangements and the respective local drive unit fails, then there can be a switchover to the assigned redundant connection. The two redundant connections, that is to say the primary connection and the secondary connection of the respective arrangement, can be connected to a single one of the local drive units or else to two mutually independent drive units. It is thus possible also to tolerate a failure of two or more connections at least two different local drive units. Furthermore, for the redundancy it is not absolutely necessary for an additional local drive unit to be kept ready on call.

With the redundantly designed connections, the fault detection unit and the providing unit, the present optical system affords the possibility of detecting connection failures and, depending thereon, dynamically rerouting the data, that is to say from the active connection to the redundant inactive connection.

A connection having a fault is a faulty connection, a disturbed connection or an interrupted connection. A fault can be a connection disturbance or a termination. Upon the occurrence of such a fault, such as a connection disturbance or a termination on one of the active connections, the previously inactive connection which is redundant with respect thereto can be used for communication with the respective arrangement and in this case for example the assigned actuator/sensor device.

The optical system can be a projection optical unit of the lithography apparatus or projection exposure apparatus. However, the optical system can also be an illumination system. The projection exposure apparatus can be an EUV lithography apparatus. EUV stands for “extreme ultraviolet” and denotes a wavelength of the operating light of between 0.1 nm and 30 nm. The projection exposure apparatus can also be a DUV lithography apparatus. DUV stands for “deep ultraviolet” and denotes a wavelength of the operating light of between 30 nm and 465 nm.

For example, the respective actuator/sensor device is an actuator (or actuating element) for actuating an optical element, a sensor for sensing an optical element or surroundings within the optical system, or an actuator and sensor device for actuating and sensing within the optical system. By way of example, the sensor is a temperature sensor. The actuator is for example an actuator using the electrostrictive effect or an actuator using the piezoelectric effect, for example a PMN actuator (PMN; lead magnesium niobate) or a PZT actuator (PZT; lead zirconate titanate). The actuator can also be a MEMS actuator (MEMS; microelectromechanical system). The actuator can be configured for example to actuate an optical element of the optical system. Examples of such an optical element include lens elements, mirrors, and adaptive mirrors.

In accordance with one embodiment, the fault detection unit is configured to detect a fault of a monitored connection of the active connections of the local drive unit on the basis of checksums of data transmitted via the monitored connection. Data from and to the actuator/sensor devices can be safeguarded by way of a checksum. Optionally, the fault detection unit continuously monitors the active connections to the connected actuator/sensor devices. Disturbed connections can be identified for example on the basis of faulty checksums over the transmitted data. In this case, it is possible to use for example a cyclic redundancy check (CRC).

In accordance with a further embodiment, the fault detection unit is configured to detect a fault of a monitored connection of the active connections of the local drive unit on the basis of a timeout of the monitored connection. Connection failures of active connections can become apparent from timeouts, for example, in which for a relatively long time data are no longer received from a specific actuator/sensor device at the connected local drive unit.

In accordance with a further embodiment, the respective interface device comprises:
a physical interface unit for physically establishing one of the primary or secondary connections,
an input buffer coupled to the physical interface unit and serving for buffer-storing data received via the physical interface unit, and
an output buffer coupled to the physical interface unit and serving for buffer-storing data to be transmitted via the physical interface unit.

The physical interface unit comprises a plug or a socket, for example. The input buffer can also be referred to as a receive buffer. The output buffer can also be referred to as a transceive buffer.

In accordance with a further embodiment, the respective local drive unit furthermore comprises:
a multiplexer coupled to the N4 input buffers,
a demultiplexer coupled to the N4 output buffers,
a storage unit for managing a channel list with a predefinable order of channels to be processed by the local drive unit, wherein a respective one of the channels is assigned to a respective one of the interface devices and one of the active connections,
a control unit coupled to the storage unit, and
a network module for coupling the local drive unit to the central drive unit.

For example, by way of the addressable channel list, the control unit controls the actuator/sensor devices to be processed and thus coordinates the data transmission and the data processing. The list entries of the channel list can be IDs or addresses. The channel list can be initially and fixedly predefined. In alternative embodiments, the channel list can be transferred from an external control device and be overwritten at the runtime. For example, the data, for example comprising configuration data, monitoring data and closed-loop control data of the actuator/sensor devices, are periodically processed in this channel list.

In accordance with a further embodiment, the control unit is configured for data processing of the data of the N1 arrangements received via the respective input buffer and the multiplexer and for controlling the demultiplexer and thus the output buffers for data transmission via the active connections to the N1 arrangements.

In accordance with a further embodiment, the providing unit is implemented as part of the network module. In this case, the network module is configured to transmit the switchover information for switching over from the active connection to the inactive connection of the specific arrangement to the central drive unit.

In accordance with a further embodiment, the central drive unit is configured to update the channel lists of the local drive units depending on the transmitted switchover information, such that the active connection of the specific arrangement is inactivated and the inactive connection of the specific arrangement is activated.

In accordance with a further embodiment, the optical system is arranged in a vacuum housing of the lithography apparatus. In this case, the network module is coupled to an external control device via an external interface device for data exchange and/or for voltage supply through the vacuum housing. The network module is configured to transmit the switchover information for switching over from the active connection to the inactive connection of the specific arrangement to the external control device. The external control device is configured to update the channel lists of the local drive units depending on the transmitted switchover information. In this case, the failure of one of the active connections is identified by the fault detection unit of the affected local drive unit (first local drive unit) and reported to the external control device via the network. The channel lists are subsequently updated by the external control device. The updated channel lists can be transmitted either at the runtime or after a re-initialization of the optical system.

In accordance with a further embodiment, the providing unit is implemented by the fault detection unit and the network module. In this case, the fault detection unit is configured to erase the channel assigned to the active connection-having the detected fault-of the specific arrangement from the channel list stored in the storage unit. The network module is configured to transmit the switchover information to the local drive unit (second local drive unit) which provides the inactive connection of the specific arrangement and which is configured to activate the inactive connection of the specific arrangement by entering the channel assigned to the inactive connection into its channel list.

Optionally, the switchover information has an instruction for activating the inactive connection of the specific arrangement and a channel number of a channel assigned to the inactive connection of the specific arrangement. The control unit of the local drive unit (second local drive unit) which provides the activated connection of the specific arrangement is configured to process the data of the specific arrangement received via the activated connection.

In this embodiment, the networked local drive units can rectify connection failures in a decentralized manner by virtue of the fact that the affected local drive unit (first local drive unit) erases from its own channel list the active connection to a specific arrangement that is no longer reliably usable, and enters into its channel list that neighboring local drive unit (second local drive unit) which provides the corresponding redundant connection to the specific arrangement. For this purpose, the switchover information can be formed by a data packet comprising an instruction for activating the redundant connection and a corresponding channel number. The correct local drive unit (second local drive unit) and the address thereof can be identified via a lookup table (LUT) or an address calculation on the basis of the defective interface ID/address. Afterward, both the communication and the data processing can be performed by that second local drive unit which provides the then activated redundant connection.

In accordance with a further embodiment, the providing unit is implemented by the fault detection unit, a packet generating unit coupled to the demultiplexer, and the network module. In this case, the fault detection unit is configured to set an indicator bit-indicating the use of the redundant connection of the specific arrangement-of a channel entry of a specific channel assigned to the connection of the specific arrangement having the detected fault. In this case, the packet generating unit is configured, during the processing of a channel entry of the channel list with the indicator bit set, to generate a first data packet having data provided by the demultiplexer for the specific channel, an instruction for activating the inactive connection of the specific arrangement, a destination address of the local drive unit (second local drive unit) which provides the inactive connection of the specific arrangement, and a channel number of a channel assigned to the inactive connection of the specific arrangement. In this case, the network module is configured to transmit the generated first data packet to the local drive unit (second local drive unit) which provides the inactive connection of the specific arrangement.

In the case of a failure of the primary communication connection, the communication can be effected via the secondary connection, although the calculation is still carried out on the primary local drive unit, such that only the data stream is redirected, without the processing location being changed. An equal distribution of the computational load across all the local drive units can continue to be ensured as a result.

For example, the second local drive unit which provides the activated connection is configured to send the received data of the first data packet to the specific arrangement via the output buffer assigned to the activated connection and to transmit response data received via the assigned input buffer in response thereto, using a second data packet, to the local drive unit which provides the inactivated connection, wherein the control unit of the local drive unit is configured to process the response data.

During the processing of a channel entry of the channel list with the indicator bit set, the packet generating unit generates a first data packet. The generated first data packet comprises the data provided by the demultiplexer for the specific channel assigned to the faulty connection, an instruction for activating the inactive connection of the specific arrangement, a destination address of the local drive unit (second local drive unit) which provides the redundant connection of the specific arrangement, and a channel number of the channel assigned to the redundant connection. The first data packet thus comprises those data which should actually be sent via the faulty connection to the specific arrangement, the instruction for activating the redundant connection with respect thereto, and the destination address of that local drive unit (second local drive unit) which provides the redundant connection. Moreover, the corresponding channel number of that channel which is assigned to the redundant connection can be added in the first data packet. Data which should be transmitted via the faulty connection are thus intercepted and transmitted via a network to the corresponding neighboring local drive unit.

In the event of a fault detection, therefore, the corresponding entry in the channel list is recorded by the corresponding indicator bit being set, such that the data are not forwarded via the local connection of the affected local drive unit (first local drive unit), but rather to the packet generating unit thereof. In the receiving second local drive unit, the first data packet is forwarded to the channel list by the network module of the unit. There, the entry of the channel list, and thus the connection kept available in a redundant manner, is activated and the data to be transmitted are stored. The control unit of the second local drive unit then starts the transmission of the data via the then activated redundant connection. Afterward, the data are read out from the input buffer of the redundant connection and in turn forwarded to the packet generating unit of the second local drive unit. In this case, the packet generating unit reads out the data from the input buffer and, together with information of the channel list, forms a second data packet, which includes in the header in turn the destination address of the first local drive unit which sends the first data packet. The second data packet is thereupon transmitted via the network. Afterward, the second data packet is forwarded to the channel list and, at positions of the entry of the channel assigned to the faulty connection, is stored in a register for alternative data arriving externally. As soon as the entry of the channel assigned to the faulty connection is intended to be processed again, the data stored in the register are fed to the fault detection unit and subsequently to the control unit, instead of the data from the input buffer. In this embodiment, the computing power remains homogeneously distributed over the plurality of local drive units, even in the case of a plurality of faulty connections or connection failures.

In accordance with a further embodiment, the optical system is in the form of an illumination optical unit or in the form of a projection optical unit of a lithography apparatus.

In accordance with a second aspect, a lithography apparatus is proposed, which comprises an optical system in accordance with the first aspect or in accordance with one of the embodiments of the first aspect.

“A(n); one” in the present case should not necessarily be understood as restrictive to exactly one element. Rather, a plurality of elements, such as for example two, three or more, can also be provided. Nor should any other numeral used here be understood to the effect that there is a restriction to exactly the stated number of elements. Rather, numerical deviations upward and downward are possible, unless indicated otherwise.

Further possible implementations of the disclosure also encompass not explicitly mentioned combinations of features or embodiments that are described above or hereinafter with respect to the exemplary embodiments. A person skilled in the art will also add individual aspects as improvements or supplementations to the respective basic form of the disclosure.

Further configurations and aspects of the disclosure are the subject matter of the dependent claims and also of the exemplary embodiments of the disclosure that are described below. The disclosure is explained in greater detail hereinafter on the basis of embodiments with reference to the accompanying figures.

### BRIEF DESCRIPTION OF THE DRAWINGS

FIG. 1 shows a schematic meridional section of a projection exposure apparatus for EUV projection lithography;

FIG. 2 shows a schematic illustration of one embodiment of an optical system with local drive units and a central drive unit;

FIG. 3 shows a schematic illustration of a second embodiment of a local drive unit for an optical system;

FIG. 4 shows a schematic illustration of a third embodiment of a local drive unit for an optical system; and

FIG. 5 shows a schematic illustration of a fourth embodiment of a local drive unit for an optical system.

### DETAILED DESCRIPTION

In the figures, identical or functionally identical elements have been provided with the same reference signs, unless indicated otherwise. Furthermore, it should be noted that the illustrations in the figures are not necessarily true to scale.

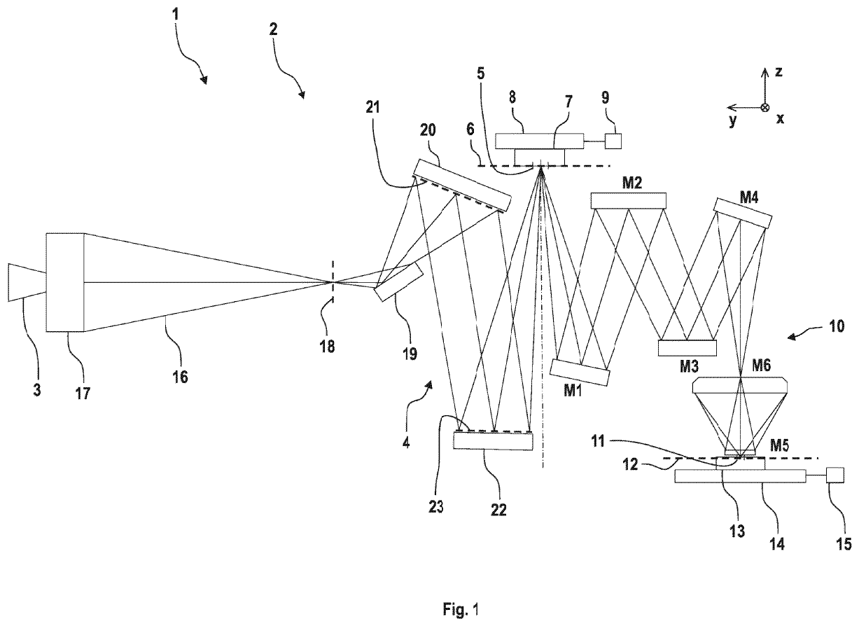

FIG. 1 shows one embodiment of a projection exposure apparatus 1 (lithography apparatus), such as an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 can also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

FIG. 1 shows, for explanation purposes, a Cartesian coordinate system with an x-direction x, a y-direction y, and a z-direction z. The x-direction x runs perpendicularly into the plane of the drawing. The y-direction y runs horizontally, and the z-direction z runs vertically. The scanning direction runs along the y-direction y in FIG. 1. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle different from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, for example along the y-direction y. The displacement firstly of the reticle 7 by way of the reticle displacement drive 9 and secondly of the wafer 13 by way of the wafer displacement drive 15 can be implemented so as to be mutually synchronized.

The light source 3 is an EUV radiation source. The light source 3 emits EUV radiation 16, which is also referred to below as used radiation, illumination radiation or illumination light. The used radiation 16 has for example a wavelength in the range of between 5 nm and 30 nm. The light source 3 can be a plasma source, for example an LPP (short for: laser produced plasma) source or a DPP (short for: gas-discharge produced plasma) source. It can also be a synchrotron-based radiation source. The light source 3 can be an FEL (short for: free-electron laser).

The illumination radiation 16 emanating from the light source 3 is focused by a collector 17. The collector 17 can be a collector having one or more ellipsoidal and/or hyperboloidal reflection surfaces. The at least one reflection surface of the collector 17 can be impinged upon by the illumination radiation 16 with grazing incidence (abbreviated as: GI), which is to say with angles of incidence greater than 45°, or with normal incidence (abbreviated as: NI), which is to say with angles of incidence less than 45°. The collector 17 can be structured and/or coated firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 can represent a separation between a radiation source module, comprising the light source 3 and the collector 17, and the illumination optical unit 4.

The illumination optical unit 4 comprises a deflection mirror 19 and, disposed downstream thereof in the beam path, a first facet mirror 20. The deflection mirror 19 can be a plane deflection mirror or, alternatively, a mirror with a beam-influencing effect that goes beyond the purely deflecting effect. Alternatively or additionally, the deflection mirror 19 can be embodied as a spectral filter separating a used light wavelength of the illumination radiation 16 from extraneous light having a wavelength that deviates therefrom. If the first facet mirror 20 is arranged in a plane of the illumination optical unit 4 that is optically conjugate to the object plane 6 as a field plane, the facet mirror is also referred to as a field facet mirror. The first facet mirror 20 comprises a multiplicity of individual first facets 21, which can also be referred to as field facets. Only some of these first facets 21 are illustrated in FIG. 1 by way of example.

The first facets 21 can be embodied as macroscopic facets, such as rectangular facets or as facets with an arcuate or partly circular edge contour. The first facets 21 can be embodied as plane facets or alternatively as convexly or concavely curved facets.

As known for example from DE 10 2008 009 600 A1, the first facets 21 themselves can also be composed in each case of a multiplicity of individual mirrors, for example a multiplicity of micromirrors. The first facet mirror 20 can be designed as a microelectromechanical system (MEMS system). For details, reference is made to DE 10 2008 009 600 A1.

The illumination radiation 16 propagates horizontally, i.e. along the y-direction y, between the collector 17 and the deflection mirror 19.

In the beam path of the illumination optical unit 4, a second facet mirror 22 is disposed downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can for example have a round, rectangular or hexagonal boundary, or can alternatively be facets composed of micromirrors. In this regard, reference is likewise made to DE 10 2008 009 600 A1.

The second facets 23 can have plane or alternatively convexly or concavely curved reflection surfaces.

The illumination optical unit 4 thus forms a doubly faceted system. This fundamental principle is also referred to as a fly's eye condenser (or fly's eye integrator).

It can be advantageous to arrange the second facet mirror 22 not exactly in a plane that is optically conjugate to a pupil plane of the projection optical unit 10. For example, the second facet mirror 22 can be arranged so as to be tilted in relation to a pupil plane of the projection optical unit 10, as described for example in DE 10 2017 220 586 A1.

With the aid of the second facet mirror 22, the individual first facets 21 are imaged into the object field 5. The second facet mirror 22 is the last beam-shaping mirror or else actually the last mirror for the illumination radiation 16 in the beam path upstream of the object field 5.

In a further embodiment (not illustrated) of the illumination optical unit 4, a transfer optical unit contributing for example to the imaging of the first facets 21 into the object field 5 can be arranged in the beam path between the second facet mirror 22 and the object field 5. The transfer optical unit can have exactly one mirror or, alternatively, two or more mirrors, which are arranged in succession in the beam path of the illumination optical unit 4. The transfer optical unit can comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20, and the second facet mirror 22.

In a further embodiment of the illumination optical unit 4, the deflection mirror 19 can also be omitted, and so the illumination optical unit 4 can then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is routinely only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a passage opening for the illumination radiation 16. The projection optical unit 10 has an image-side numerical aperture which is greater than 0.5 and which can also be greater than 0.6 and which, for example, can be 0.7 or 0.75.

Reflection surfaces of the mirrors Mi can be embodied as freeform surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, for example with alternating layers of molybdenum and silicon.

The projection optical unit 10 has a large object-image offset in the y-direction y between a y-coordinate of a center of the object field 5 and a y-coordinate of the center of the image field 11. This object-image offset in the y-direction y can be of approximately the same magnitude as a z-distance between the object plane 6 and the image plane 12.

For example, the projection optical unit 10 can have an anamorphic configuration. It has for example different imaging scales βx, βy in the x-and y-directions x, y. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, i.e. in a direction perpendicular to the scanning direction.

The projection optical unit 10 leads to a reduction in size of 8:1 in the y-direction y, i.e. in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 can be the same or can differ, depending on the embodiment of the projection optical unit 10. Examples of projection optical units with different numbers of such intermediate images in the x-direction x and y-direction y are known from US 2018/0074303 A1.

In each case, one of the second facets 23 is assigned to exactly one of the first facets 21 for forming in each case an illumination channel for illuminating the object field 5. For example, this can produce illumination according to the Köhler principle. The far field is decomposed into a multiplicity of object fields 5 with the aid of the first facets 21. The first facets 21 generate a plurality of images of the intermediate focus on the second facets 23 respectively assigned to them.

The first facets 21 are each imaged onto the reticle 7 by an assigned second facet 23 and overlaid over one another for the purpose of illuminating the object field 5. The illumination of the object field 5 is for example as homogeneous as possible. It can have a uniformity error of less than 2%. Field uniformity can be attained by overlaying different illumination channels.

The illumination of the entrance pupil of the projection optical unit 10 can be defined geometrically by an arrangement of the second facets 23. The intensity distribution in the entrance pupil of the projection optical unit 10 can be set by selecting the illumination channels, for example the subset of the second facets 23, which guide light. This intensity distribution is also referred to as illumination setting or illumination pupil filling.

A likewise preferred pupil uniformity in the region of portions of an illumination pupil of the illumination optical unit 4 which are illuminated in a defined manner can be achieved by a redistribution of the illumination channels.

Further aspects and details of the illumination of the object field 5 and for example of the entrance pupil of the projection optical unit 10 are described below.

The projection optical unit 10 can have for example a homocentric entrance pupil. The latter can be accessible. It can also be inaccessible.

The entrance pupil of the projection optical unit 10 regularly cannot be exactly illuminated with the second facet mirror 22. In the case of imaging by the projection optical unit 10 which telecentrically images the center of the second facet mirror 22 onto the wafer 13, the aperture rays often do not intersect at a single point. However, it is possible to find an area in which the spacing of the aperture rays that is determined in pairs becomes minimal. This area represents the entrance pupil or an area conjugate thereto in real space. For example, this area exhibits a finite curvature.

It may be the case that the projection optical unit 10 has different positions of the entrance pupil for the tangential beam path and for the sagittal beam path. In this case, an imaging element, for example an optical component of the transfer optical unit, should be provided between the second facet mirror 22 and the reticle 7. With the aid of this optical element, the different positions of the tangential entrance pupil and the sagittal entrance pupil can be taken into account.

In the arrangement of the components of the illumination optical unit 4 illustrated in FIG. 1, the second facet mirror 22 is arranged in an area conjugate to the entrance pupil of the projection optical unit 10. The first facet mirror 20 is arranged so as to be tilted with respect to the object plane 6. The first facet mirror 20 is arranged so as to be tilted with respect to an arrangement plane defined by the deflection mirror 19. The first facet mirror 20 is arranged so as to be tilted with respect to an arrangement plane defined by the second facet mirror 22.

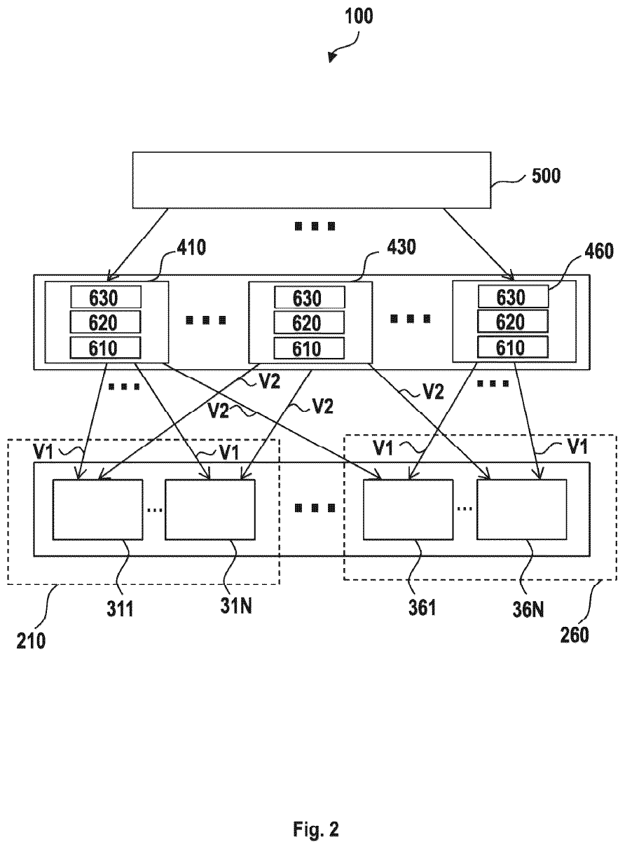

FIG. 2 shows a schematic illustration of one embodiment of an optical system 100 for a lithography apparatus or projection exposure apparatus 1, as shown in FIG. 1, for example. Additionally, the optical system 100 in FIG. 2 can also be used in a DUV lithography apparatus, for example.

The optical system 100 comprises a number N1 of arrangements, where N1≥1, wherein each of the N1 arrangements 210-260 comprises at least one actuator/sensor device 311-31N, 361-36N assigned to one of the optical elements. The actuator/sensor device 311-31N, 361-36N is for example an actuator device for displacing the optical element, a sensor device for determining a position of the optical element or an actuator and sensor device for displacing the optical element and for determining a position of the optical element.

Furthermore, the optical system 100 comprises a plurality N2 of local drive units 410-460 for driving the number N1 of arrangements 210-260, where N2≥2. Moreover, the optical system 100 a number N3 of central drive units 500 for driving the N2 local drive units 410-460, where N3≥1. In this case, N1, N2, N3 are natural numbers, for example. Without restricting generality, N3=1 in FIG. 2.

Each of the N2 local drive units 410-460 is coupled to each of the N3 central drive units 500 for example in such a way that each of the N2 local drive units 410-460 is drivable by each of the N3 central drive units 500. Furthermore, each of the N2 local drive units 410-460 can be connected to at least two of the N1 arrangements 210-260, where 2≤N2<N1.

In accordance with FIG. 2, the optical system 100 comprises one central drive unit 500 (N3=1), six local drive units 410-460 (N2=6) and 6·N actuator/sensor devices 311-31N, 361-36N. Without restricting generality, in the embodiment in FIGS. 2, N2=6 and N1=6·N. The central drive unit 500, the six local drive units 410-460 and the 6·N arrangements 210-260 in FIG. 2 are arranged in a tree structure B. The tree structure B in FIG. 2 is based on a rooted tree in which the central drive unit 500 forms the root, the local drive units 410-460 form the inner nodes and the arrangements 210-260 form the leaves. An alternative structure to the tree structure B in FIG. 2 is a ring structure, for example.

Each of the N1 arrangements 210-260 is connected to at least one of the N2 local drive units 410-460 via a primary connection V1 and a secondary connection V2. The primary connection V1 and the secondary connection V2 are redundant with respect to one another. In this case, one of the connections V1, V2 is usable as an active connection for data transmission, and the other of the two connections V2, V1 is inactive and is available as a redundancy device. The primary connection V1 and the secondary connection V2 can be connected to two different local drive units 410-460 (as shown in FIG. 2). Alternatively, the primary connection V1 and the secondary connection V2 are connected to a single local drive unit 410-460 (not shown).

Each of the local drive units 410-460 comprises an interface device 610, a fault detection unit 620 and a providing unit 630. The interface device 610 is configured for establishing the primary connection V1 or the secondary connection V2 to one of the N1 arrangements 210-260.

The fault detection unit 620 is configured to detect a fault of one of the active connections V1, V2 of a specific one of the N1 arrangements 210-260. Therefore, if one of the active connections, which can be a primary connection V1 or a secondary connection V2, is affected by a fault, then the fault detection unit 620 detects this fault.

For reasons of simplified illustration, hereinafter an active connection before a fault detection is designated by V1, whereas a connection which is inactive before the time of the fault detection and to which there is a switchover after the fault detection is designated by V2.

In this case, the fault detection unit 620 is configured for example to detect such a fault of a monitored connection of the active connections V1 of the local drive unit 410-460 on the basis of checksums of data transmitted via the monitored connection.

By way of example, the fault detection unit continuously monitors the active connections to the N1 arrangements. Disturbed connections can be identified for example on the basis of faulty checksums over the transmitted data packets. In this case, it is possible to use for example a cyclic redundancy check (CRC).

Alternatively or additionally, the respective fault detection unit 620 is configured to detect a fault of a monitored connection of the active connections V1 of the local drive unit 410-460 on the basis of a timeout of the monitored connection. Connection failures of active connections V1 can become apparent from timeouts, for example, in which for a relatively long time data are no longer received from a specific one of the N1 arrangements 210-260 at the respective local drive unit 410-460.

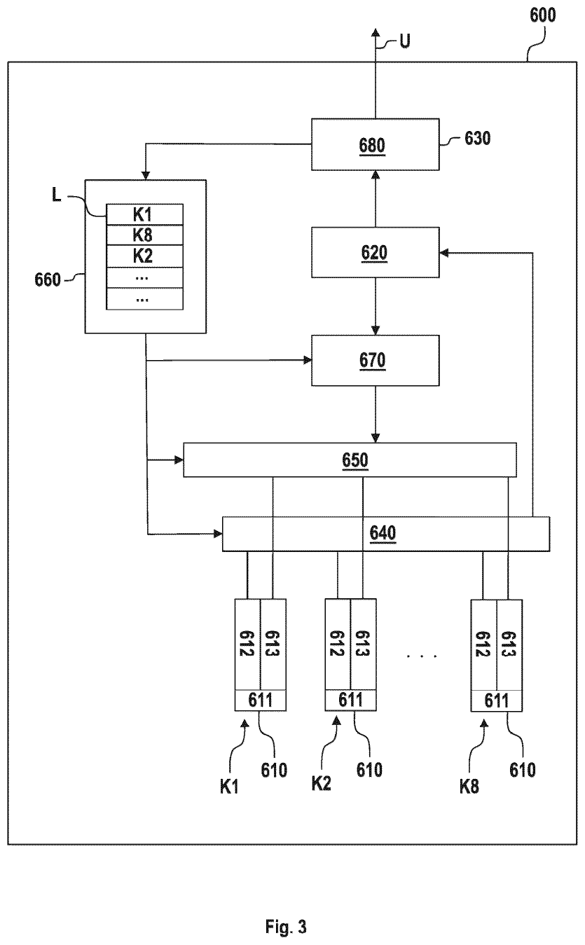

If a fault is then detected on an active connection V1, there is a switchover to the secondary connection V2 that is redundant with respect to this faulty connection. For this purpose, the providing unit 630 of the local drive unit 410-460 is configured to provide switchover information U (see FIGS. 3-5, for example) for switching over the active connection V1 having a detected fault to the inactive connection V2 of the specific arrangement 210-260 that is redundant with respect thereto. Therefore, if an active connection V1 is faulty, the switchover information U provided is used to switch over to the secondary connection V2 that is redundant with respect to the active connection.

With regard to providing and using the switchover information U, FIGS. 3-5 show different embodiments of a local drive unit 600 for an optical system 100 as illustrated in FIG. 2. For example, the respective local drive unit 600 in FIGS. 3-5 constitutes an embodiment for the local drive units 410-460 illustrated in FIG. 2.

The local drive unit 600 in FIG. 3 comprises a plurality of interface devices 610, a fault detection unit 620, a providing unit 630, a multiplexer 640, a demultiplexer 650, a storage unit 660, a control unit 670 and a network module 680.

Each of the plurality of interface devices 610 has a physical interface unit 611, an input buffer 612 coupled to the physical interface unit 611, and an output buffer 613 coupled to the physical interface unit 611. The input buffer 612 can also be referred to as a receive buffer. The output buffer 613 can also be referred to as a transceive buffer. The physical interface unit 611 is configured for physically establishing the primary connection or the secondary connection V1, V2. The physical interface unit 611 comprises a plug, for example. The input buffer 612 is configured for buffer-storing data received via the physical interface unit 611, received from the respectively connected arrangement 210-260. The output buffer 613 is configured for buffer-storing data to be transmitted to the connected arrangement 210-260 via the physical interface unit 611.

The plurality of input buffers 611 are coupled to the multiplexer 640. The plurality of output buffers 613 are coupled to the demultiplexer 650.

The storage unit 660 stores and manages a channel list L. The channel list L comprises a predefinable order of channels K1-K8 to be processed by the local drive unit 600. FIG. 3 illustrates one exemplary order in this respect. A respective one of the channels K1-K8 is assigned to a respective one of the interface devices 610 and thus to a respective one of the active connections V1. By way of example, the left interface device 610 in FIG. 3 is assigned to the channel K1. The interface device 610 adjacent thereto is assigned to the channel K2, for example, and the interface device 610 illustrated on the far right is assigned to the channel K8, for example.

The channel K1-K8 to be processed in each case is provided by the storage unit 660, on the output side, to the multiplexer 640, the demultiplexer 650 and the control unit 670. For this purpose, the control unit 670 is coupled to the storage unit 660. The control unit 670 is configured for data processing of the data of the respective one of the N1 arrangements 210-260 received via the respective input buffer 612 and the multiplexer 640 and for controlling the demultiplexer 650 and thus the output buffers 613 for data transmission via the active connections V1 to the N1 arrangements 210-260.

The network module 680 of the local drive unit 600 in FIG. 3 is configured for coupling the local drive unit 600 to the central drive unit 500. Alternatively or additionally, the local drive unit 600 can be coupled to a data bus via the network model 680.

In the exemplary embodiment according to FIG. 3, the providing unit 630 is implemented as part of the network module 680. In this case, the network module 680 is configured to transmit the switchover information U for switching over from the active connection V1 to the inactive connection V2 of the specific arrangement 210-260 to the central drive unit 500. In this case, the switchover information U indicates that the active connection V1 which is faulty is to be inactivated and the connection V2 which is redundant with respect to the active connection V1 is to be activated for data transmission. For this purpose, the switchover information U is transmitted to that local drive unit 410-460 which provides the redundant connection V2.

In this case, the central drive unit 500 is configured to update the channel lists L of the local drive units 410-460, 600 depending on the transmitted switchover information U, such that the active connection V1 of the specific arrangement 210-260 is inactivated and the inactive connection V2 (redundant with respect to the faulty connection V1) of the specific arrangement 210-260 is activated. As described, in this case, the central drive unit 500 can be the actuator pertaining to the updating of the channel lists L of the local drive units 410-460, 600. In alternative embodiments, it is also possible for the actuator pertaining to the updating of the channel lists L to be an external control device arranged externally vis-à-vis the optical system 100. In this case, it should be noted that the optical system 100 can be arranged in a vacuum housing of the lithography apparatus 1. The network module 680 can be coupled to the external control device via an external interface device for data exchange and/or for voltage supply through the vacuum housing. The network module 680 can then be configured to transmit the switchover information U for switching over from the active connection V1 to the inactive connection V2 of the specific arrangement 210-260 to the external control device. For this purpose, the external control device can be configured to update the channel lists L of the local drive units 410-460, 600 depending on the transmitted switchover information U.

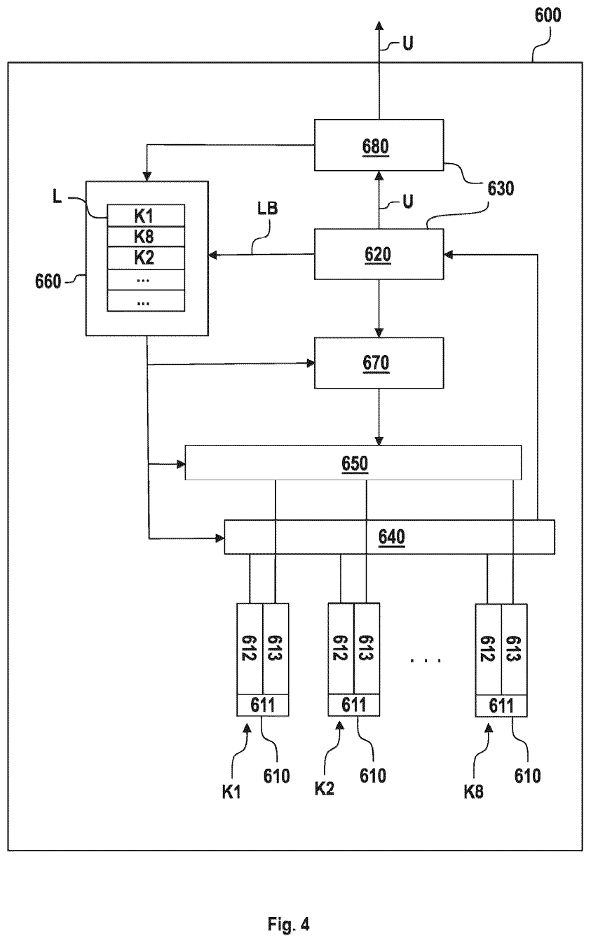

Furthermore, FIG. 4 shows a schematic illustration of a third embodiment of a local drive unit 600 for an optical system 100. The architecture of the local drive unit 600 according to FIG. 4 corresponds to that in FIG. 3. The embodiment according to FIG. 4 differs from that according to FIG. 3 in the implementation of the providing unit 630. In the embodiment according to FIG. 4, the providing unit 630 is implemented by the fault detection unit 620 and the network module 680. In this case, the fault detection unit 620 is configured to erase that channel, for example the channel K2, which has the detected fault and is assigned to a specific active connection V1 of the specific arrangement 210-260 from the channel list L stored in the storage unit 660. For this purpose, the fault detection unit 620 uses an erase command LB, for example, by which it erases the channel entry K2 from the channel list L of the storage unit 660. Furthermore, the network module 680 in FIG. 4 is configured to transmit the switchover information U to the local drive unit 410-460, 600 which provides the inactive connection V2 of the specific arrangement 210-260. Here-as explained above-the inactive connection V2 is that connection which is redundant with respect to the connection V1 having the fault. In this case, the local drive unit 410-460, 600 which provides the inactive connection V2 is configured to activate the inactive connection V2 of the specific arrangement 210-260 by entering the channel assigned to the inactive connection V2 into its channel list L.

In this case, the switchover information U can comprise an instruction for activating the inactive connection V2 of the specific arrangement 210-260 and a channel number of the channel assigned to the inactive connection V2 of the specific arrangement 210-260. The control unit 670 of the local drive unit 410-460, 600 which provides the activated connection V2 of the specific arrangement 210-260 is then configured to process the data of the specific arrangement 210-260 received via the activated connection V2.

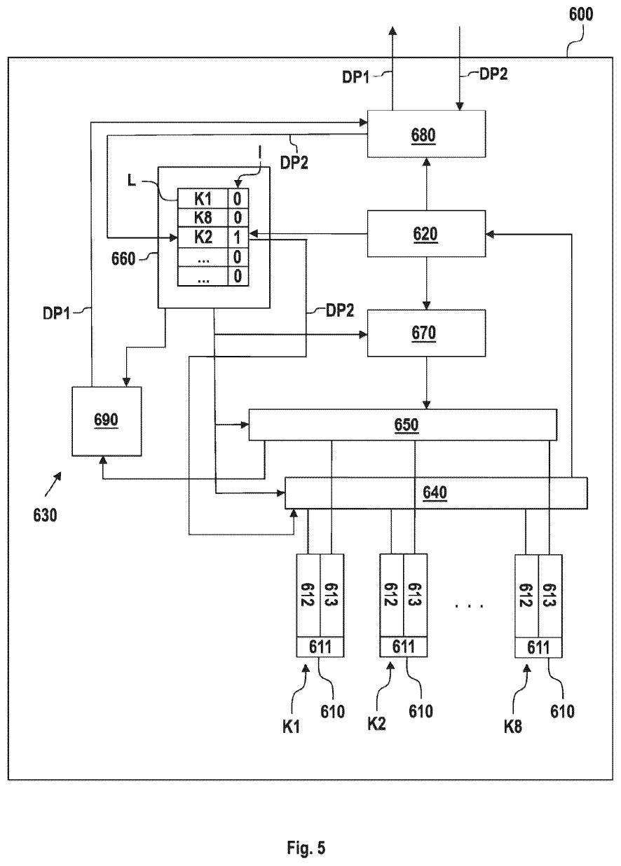

FIG. 5 illustrates a schematic illustration of a fourth embodiment of a local drive unit 600 for an optical system 100. The fourth embodiment according to FIG. 5 differs in the implementation of the providing unit 630. In the embodiment according to FIG. 5, the providing unit 630 is implemented by the fault detection unit 620, a packet generating unit 690 coupled to the demultiplexer 650, and the network module 680. In this case, the fault detection unit 620 is configured to set an indicator bit I—indicating the use of the redundant connection V2 of the specific arrangement 210-260—of a channel entry of a specific channel K2 assigned to the connection V1 of the specific arrangement 210-260 having the detected fault. That is to say that the channel list L is extended by an indicator bit I with regard to each channel entry. If a specific active connection V1 assigned to a specific channel, here K2, for example, has a fault, then the fault detection unit 620 sets the corresponding indicator bit I in the channel list L, in the channel entry for the channel K2 of the channel list L in the example in FIG. 5.

In this case, the packet generating unit 690 is configured to generate a first data packet DP1 during the processing of a channel entry of the channel list L with the indicator bit I set, the channel entry K2 of the channel list L in the example in FIG. 5. The first data packet DP1 comprises data provided by the demultiplexer 650 for the specific channel K2, an instruction for activating the inactive connection V2 of the specific arrangement 210-260 (hence the connection V2 which is redundant with respect to the faulty active connection V1), a destination address of the local drive unit 410-460, 600 which provides the redundant connection V2 of the specific arrangement 210-260, and a channel number of the channel assigned to the redundant connection V2 of the specific arrangement 210-260. The first data packet DP1 thus comprises those data which should actually be sent via the faulty connection to the specific arrangement 210-260, the instruction for activating the redundant connection V2 with respect thereto, and the destination address of that local drive unit 410-460, 600 which provides the redundant connection V2. Moreover, the corresponding channel number of the channel assigned to the redundant connection V2 is added to the first data packet DP1.

The network module 680 is then configured to transmit the generated first data packet DP1 to the local drive unit 410-460, 600 which provides the activated connection V2 of the specific arrangement 210-260.

The local drive unit 410-460, 600 which receives the first data packet DP1 is then configured to send the received data of the first data packet DP1 to the specific arrangement 210-260 via the output buffer 613 assigned to the activated connection V2 and to receive response data received via the assigned input buffer 612 in response thereto. These received response data are transmitted using a second data packet DP2 to the local drive unit 410-460, 600 which provides the inactivated connection V1, wherein the control unit 670 of the local drive unit can then process these response data.

Although the present disclosure has been described on the basis of exemplary embodiments, it is modifiable in diverse ways.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Optical system
210-260 Arrangement
311-31N Actuator/sensor device
321-32N Actuator/sensor device
331-33N Actuator/sensor device
341-34N Actuator/sensor device
351-35N Actuator/sensor device
361-36N Actuator/sensor device
410-460 Local drive unit
500 Central drive unit
600 Local drive unit
610 Interface device
611 Physical interface unit
612 Input buffer
613 Output buffer
620 Fault detection unit
630 Providing unit
640 Multiplexer
650 Demultiplexer
660 Storage unit for channel list
670 Control unit
680 Network module
690 Packet generating unit
DP1 First data packet
DP2 Second data packet
I Indicator bit
K1-K8 Channel
L Channel list
LB Erase command
M1 Mirror
M2 Mirror
M3 Mirror
M4 Mirror
M5 Mirror
M6 Mirror
U Switchover information
V1 Primary connection
V2 Secondary connection

What is claimed is:

1. An optical system, comprising:
a plurality of optical elements;
a number N1 of arrangements, each of the N1 arrangements comprising an actuator/sensor device assigned to one of the optical elements;
a plurality N2 of local drive units configured to drive the number N1 of arrangements; and
a number N3 of central drive units configure to drive the N2 local drive units,
wherein:
N1 at least one;
N2 is at least two;
N3 is at least one;
each of the N1 arrangements is connected to at least one of the N2 local drive units via a primary connection and a secondary connection, the secondary connection being redundant with respect to the primary connection, one of the connections being usable as an active connection to transmit data and the other of the connections being inactive;
each of the N2 local drive units comprises:
a plurality N4 of interface devices, each of the N4 interface devices being configured to establish the primary connection or the secondary connection to one of the N1 arrangements;
a fault detection unit configured to detect a fault of one of the active connections of the one of the N1 arrangements; and
a providing unit configured to provide, when a fault is detected for the active connection of the one of the N1 arrangements, switchover information to switch the active connection to the inactive connection of the one of the N1 arrangements; and
N4 is at least two.

2. The optical system of claim 1, wherein, for each of the fault detection units, the fault detection unit is configured to detect a fault of the active connection of its the local drive unit based on checksums of data transmitted via the active connection.

3. The optical system of claim 2, wherein each interface device comprises:
a physical interface unit configured to physically establishing its primary or secondary connection;
an input buffer coupled to the physical interface unit, the input buffer configured to buffer-store data received via the physical interface unit; and
an output buffer coupled to the physical interface unit, the output buffer configured to buffer-store data to be transmitted via the physical interface unit.

4. The optical system of claim 1, wherein, for each of the fault detection units, the fault detection unit is configured to detect a fault of the active connection of its local drive unit based on a timeout of the active connection.

5. The optical system of claim 4, wherein each interface device comprises:
a physical interface unit configured to physically establishing its primary or secondary connection;
an input buffer coupled to the physical interface unit, the input buffer configured to buffer-store data received via the physical interface unit; and
an output buffer coupled to the physical interface unit, the output buffer configured to buffer-store data to be transmitted via the physical interface unit.

6. The optical system of claim 1, wherein each interface device comprises:
a physical interface unit configured to physically establishing its primary or secondary connection;
an input buffer coupled to the physical interface unit, the input buffer configured to buffer-store data received via the physical interface unit; and
an output buffer coupled to the physical interface unit, the output buffer configured to buffer-store data to be transmitted via the physical interface unit.

7. The optical system of claim 6, wherein each local drive unit further comprises:
a multiplexer coupled to each of the input buffers;
a demultiplexer coupled to each of the output buffers;
a storage unit configured to manage a channel list with a predefinable order of channels to be processed by the local drive unit, each channel being assigned to a respective one of the interface devices and one of the active connections;
a control unit coupled to the storage unit; and
a network module coupling the local drive unit to the central drive unit.

8. The optical system of claim 7, wherein the control unit is configured to: i) process the data of the N1 arrangements received via the respective input buffer and the multiplexer; and ii) control the demultiplexer, and thus the output buffers, for data transmission via the active connections to the N1 arrangements.

9. The optical system of claim 8, wherein the providing unit is implementable as part of the network module, and the network module is configured to transmit the switchover information to switch over from the active connection to the inactive connection of the one of the N1 arrangements to the central drive unit.

10. The optical system of claim 8, wherein:
the providing unit is implementable by the fault detection unit, a packet generating unit coupled to the demultiplexer, and the network module;
the fault detection unit is configured to set an indicator bit, indicating the use of the redundant connection of the specific arrangement, of a channel entry of a specific channel assigned to the one of the N1 connections having the detected fault;
the packet generating unit is configured, during processing of a channel entry of the channel list with the indicator bit set, to generate: i) a first data packet comprising data provided by the demultiplexer for the specific channel; ii) an instruction to activate the inactive connection of the one of the N1 arrangements; iii) a destination address of the local drive unit which provides the inactive connection of the specific arrangement; and iv) a channel number of a channel assigned to the inactive connection of the specific arrangement; and
the network module is configured to transmit the generated first data packet to the local drive unit which provides the inactive connection of the one of the N1 arrangements.

11. The optical system of claim 7, wherein the providing unit is implementable as part of the network module, and the network module is configured to transmit the switchover information to switch over from the active connection to the inactive connection of the one of the N1 arrangements to the central drive unit.

12. The optical system of claim 11, wherein the central drive unit is configured to update the channel lists of the local drive units depending on the transmitted switchover information so that the active connection of one of the N1 arrangements is inactivated and the inactive connection of the one of the N1 arrangements is activated.

13. The optical system of claim 11, wherein:
the optical system is in a vacuum housing of an apparatus;
the network module is coupled to an external control device via an external interface device to exchange and/or to supply voltage through the vacuum housing;
the network module is configured to transmit the switchover information to switch over from the active connection to the inactive connection of the one of the N1 arrangements to the external control device; and
the external control device is configured to update the channel lists of the local drive units depending on the transmitted switchover information.

14. The optical system of claim 7, wherein:
the providing unit is implementable by the fault detection unit and the network module;
the fault detection unit is configured to erase the channel assigned to the active connection having the detected fault of the one of the N1 arrangements from the channel list stored in the storage unit; and
the network module is configured to transmit the switchover information to the local drive unit which provides the inactive connection of the one of the N1 arrangements and which is configured to activate the inactive connection of the one of the N1 arrangements by entering the channel assigned to the inactive connection into its channel list

15. The optical system of claim 14, wherein:
the switchover information comprises:
an instruction to activate the inactive connection of the one of the N1 arrangements; and
a channel number of a channel assigned to the inactive connection of the specific arrangement; and
the control unit of the local drive unit which provides the activated connection of the one of the N1 arrangements is configured to process the data of the specific arrangement received via the activated connection.

16. The optical system of claim 7, wherein:
the providing unit is implementable by the fault detection unit, a packet generating unit coupled to the demultiplexer, and the network module;
the fault detection unit is configured to set an indicator bit, indicating the use of the redundant connection of the specific arrangement, of a channel entry of a specific channel assigned to the one of the N1 connections having the detected fault;
the packet generating unit is configured, during processing of a channel entry of the channel list with the indicator bit set, to generate: i) a first data packet comprising data provided by the demultiplexer for the specific channel; ii) an instruction to activate the inactive connection of the one of the N1 arrangements; iii) a destination address of the local drive unit which provides the inactive connection of the specific arrangement; and iv) a channel number of a channel assigned to the inactive connection of the specific arrangement; and
the network module is configured to transmit the generated first data packet to the local drive unit which provides the inactive connection of the one of the N1 arrangements.

17. The optical system of claim 16, wherein:
the local drive unit which provides the activated connection is configured to: i) send the received data of the first data packet to the one of the N1 arrangements via the output buffer assigned to the activated connection; and ii) transmit response data received via the assigned input buffer in response thereto, using a second data packet, to the local drive unit which provides the inactivated connection; and
the control unit of the local drive unit is configured to process the response data.

18. An apparatus, comprising:
an optical system according to claim 1,
wherein the apparatus is a lithography apparatus.

19. The apparatus of claim 18, further comprising a projection optical unit, wherein the projection optical unit comprises the optical system according to claim 1.

20. The apparatus of claim 18, further comprising an illumination system, wherein the projection optical unit comprises the optical system according to claim 1.
